(19) United States
(12) Patent Application Publication
(10) Pub. No.: US 2021/0286324 A1
(43) Pub. Date: Sep. 16, 2021

(54) COMPENSATOR, CONTROL SYSTEM, COMPENSATION METHOD, AND PROGRAM

(71) Applicant: MITSUBISHI HEAVY INDUSTRIES, LTD., Tokyo (JP)

(72) Inventors: Takaharu HIROE, Tokyo (JP); Kazunari IDE, Tokyo (JP); Ryo SASE, Tokyo (JP)

(21) Appl. No.: 17/162,485

(22) Filed: Jan. 29, 2021

(30) Foreign Application Priority Data
Mar. 12, 2020 (JP) 2020-043024

(51) Int. Cl. G05B 6/02

(52) U.S. Cl. CPC G05B 6/02

(57) ABSTRACT

A compensator includes a processor, and a storage device that is connected to the processor and stores measured input values that are measured values of an input to a subject to control and measured output values that are measured values of an output from the subject to control. The processor performs processing for identifying, from the measured input values and the measured output values, a first coefficient configuring a finite impulse response filter, processing for determining, based on the first coefficient, a second coefficient configuring an infinite impulse response filter, and identifying an inverse system for the subject to control, the inverse system including the second coefficient and a part of the first coefficient, and processing for estimating an input value to be input to the subject to control from a weighted sum of target values of the output.

### CROSS-REFERENCE TO RELATED APPLICATIONS

This application claims the benefit of priority to Japanese Patent Application Number 2020-043024 filed on Mar. 12, 2020. The entire contents of the above-identified application are hereby incorporated by reference

### TECHNICAL FIELD

The present disclosure relates to a compensator, a control system, a compensation method, and a program.

### RELATED ART

In an industrial control system, an ideal state is a state in which output of a subject to control perfectly tracks a target value. In order to achieve this, it is effective to use a feed-forward compensator while using a model for the subject to control. Feedback is the opposite of feed-forward and operates based on the target value and a deviation of the output from the target value. Thus, when the target value changes at a high frequency, it is difficult to avoid a delay in tracking. Further, in order to suppress a tracking delay, a slight deviation needs to be amplified and then compensated for. However, as is well known, since oscillation occurs when an amplification factor of the deviation is increased, there is an upper limit to the amplification factor. Thus, it is difficult to eliminate the deviation using only feedback compensation.

In contrast, feed-forward compensation calculates an input so that the output of the subject to control matches the target value. In this calculation, the model for the subject to control plays an important role. This is because, if the model is accurate, when the calculated input is applied to the subject to control, the output of the subject to control matches the target value. Thus, it is critical to obtain an accurate model. Since the actual subject to control changes over time due to changes in the operating state, deterioration of a device, and the like, the model also needs to be updated in accordance with those changes.

For example, assuming that the model is updated at a time t, it is common to identify the model using a discrete-time autoregressive moving average (ARMA) transfer function model, such as Equation (1) described below, or an infinite impulse response (IIR) filter, based on most recent historical values uᵢ (i=t−1, t−2, t−3, . . . ) of the input to the subject to control, and most recent historical values yᵢ (i=t−1, t−2, t−3, . . . ) of the output from the subject to control (see JP 2010-86395 A, for example).

$$\begin{matrix}[ Equation 1 ] & \\ P = \frac{{a}_{1} {z}^{- 1} + {a}_{2} {z}^{- 2} + … + {a}_{N} {z}^{- n}}{1 + {b}_{1} {z}^{- 1} + {b}_{2} {z}^{- 2} + … + {b}_{N} {z}^{- n}} , \\ y = Pu & ( 1 )\end{matrix}$$

In Equation (1), z⁻¹ is a delay operator, and {a₁, a₂, . . . , aₙ, b₁, b₂, . . . , bₙ} are tuning parameters of the model. The tuning parameters of the model are determined, for example, by the least squares method.

### SUMMARY

Here, when a target value is denoted as r, an ideal state is obtained when “y=r” is established. When an input to achieve the ideal state is denoted as “\hat{ }u” (corresponding to a notation obtained by attaching a hat symbol to “u”), since “P\hat{ }u=r” needs to be established, the input of the ideal state is denoted by “\hat{ }u=P⁻¹r”. Here, P⁻¹ is a transfer function for determining the input from the output of the subject to control, and is referred to as an inverse system. However, there are two problems with this. The first problem is that the inverse system P⁻¹ has a numerator degree that is larger than a denominator degree. As a result, it is difficult to numerically calculate P⁻¹. The second problem is that there is a possibility that an absolute value of the root of the characteristic polynomial of the denominator of P⁻¹ may exceed 1. If the absolute value of the root exceeds 1, P⁻¹ becomes unstable, and the numerical calculation diverges. The first problem can be solved by making a modification, for example, by replacing the target value with “rz⁻¹”, as expressed in Equation (2) below, so that the output always tracks the target value one step behind. This is equivalent to designating a reference model (an ideal response model) for the target value as z⁻¹.

$$\begin{matrix}[ Equation 2 ] & \\ \hat{u} = {P}^{- 1} {z}^{- 1} r = \frac{1 + {b}_{1} {z}^{- 1} + {b}_{2} {z}^{- 2} + … + {b}_{n} {z}^{- n}}{{a}_{1} + {a}_{2} {z}^{- 1} + … + {a}_{n} {z}^{- n + 1}} r & ( 2 )\end{matrix}$$

However, with known technology, it is difficult to solve the instability in the second problem. Particularly, the inverse system P⁻¹ of the subject to control performs estimation from historical input and output values, and the estimated value has an error with respect to an actual value. Reasons for the error include differences between recorded values and the actual values, which arise from errors in a valve, an actuator, or a sensor, noise that is always included in measured input and output values used for the estimation, and the like. For practical purposes, even when such an error exists, it is necessary to accurately estimate P⁻¹.

As described above, the model is updated based on the historical data. From a practical point of view, it is important to determine how much of the historical data should be used, and using fewer historical data is more preferable. This is because, if the model can be updated with a small amount of data, even when characteristics of the subject to control have changed within a short period of time, the model can be updated capturing those changes. For example, here, it is assumed that the characteristics of the subject to control have changed over 10 minutes. At this time, if the model can be updated using observation values obtained over the past one minute, a prediction model can be updated in accordance with these changes. However, if updating the model requires observation values for the past 60 minutes, the model can be only updated after tens of minutes have elapsed since the change occurred in a subject to be predicted, and there is a possibility that the prediction may be different from reality. In the above-described model estimation, the estimation accuracy has an inverse relationship with the amount of data to be used. To ensure the accuracy of the model estimation, it is necessary to go further back in the past and use a larger amount of data. On the other hand, to estimate the model using only recent data, estimation accuracy needs to be sacrificed.

In light of the foregoing, the present disclosure provides a compensator, a control system, a compensation method, and a program that can accurately calculate an input value to be input to a subject to control from a small amount of data.

According to an aspect of the present disclosure, a compensator includes a processor, and a storage device connected to the processor and configured to store a measured input value that is a measured value of an input to a subject to control and a measured output value that is a measured value of an output from the subject to control. The processor performs processing for identifying, from the measured input value and the measured output value, a first coefficient {g₁, g₂, g₃ . . . } configuring a finite impulse response filter expressed as g₁z⁻¹+g₂z⁻²+g₃z⁻³+ . . . , processing for determining, based on the first coefficient, a second coefficient {h₁, h₂, h₃ . . . } configuring an infinite impulse response filter so that a transfer function has a numerator of g₁z⁻¹ and a denominator of 1−h₁z⁻¹, −h₂z⁻²−h₃z⁻³− . . . , and identifying an inverse system that is a system including the second coefficient and a part of the first coefficient and configured to identify a target value of the input from a target value of the output of the subject to control, and processing for estimating an input value to be input to the subject to control from a weighted sum of the target value of the output set in accordance with a time, based on the inverse system.

According to an aspect of the present disclosure, a compensator includes a processor, and a storage device connected to the processor, and configured to store a measured input value that is a measured value of an input to a subject to control, and a measured output value that is a measured value of an output from the subject to control. The processor performs processing for determining, from the measured input value and the measured output value, a second coefficient {h₁, h₂, h₃ . . . } configuring an infinite impulse response filter so that a transfer function has a denominator polynomial of 1−h₁z⁻¹, −h₂z⁻²−h₃z⁻³− . . . and a numerator of g₁z⁻¹, and a first coefficient {g₁}, and identifying an inverse system, including the second coefficient, for the subject to control, and processing for calculating an input value to be input to the subject to control from a weighted sum of the target value of the output set in accordance with a time, based on the inverse system.

According to an aspect of the present disclosure, a compensator includes a processor, and a storage device connected to the processor, and configured to store, in advance, a measured input value that is a measured value of an input to a subject to control, a measured output value that is a measured value of an output from the subject to control, a plurality of first coefficients respectively configuring a plurality of model candidates for the subject to control, and an inverse system that corresponds to each of the plurality of model candidates, the inverse system being configured to identify a target value of the input from a target value of the output from the subject to control. The processor performs processing for estimating a likelihood of each of the plurality of model candidates based on the measured output value, and an estimated value of the output obtained from the plurality of first coefficients and the measured input value, processing for selecting the model candidate having the highest estimated likelihood, and processing for calculating an input value to be input to the subject to control from a weighted sum of the target value of the output set in accordance with a time, based on the inverse system corresponding to the selected model candidate.

According to an aspect of the present disclosure, a compensator includes a processor, and a storage device connected to the processor and configured to store, in advance, a measured input value that is a measured value of an input to a subject to control, a measured output value that is a measured value of an output from the subject to control, and a plurality of first coefficients respectively configuring a plurality of model candidates for the subject to control. The processor performs processing for estimating a likelihood of each of the plurality of model candidates based on the measured output value, and an estimated value of the output obtained from the plurality of first coefficients and the measured input value, processing for deriving a third coefficient that is a weighted average of the first coefficient of each of the model candidates, using the likelihood as a weighting factor, processing for determining, based on the third coefficient, a second coefficient configuring an infinite impulse response filter, and identifying an inverse system that is a system including the second coefficient and a part of the third coefficient and configured to identify a target value of the input from a target value of the output from the subject to control, and processing for estimating an input value to be input to the subject to control from a weighted sum of the target value of the output set in accordance with a time, based on the inverse system.

According to an aspect of the present disclosure, a compensation method includes identifying a first coefficient configuring a finite impulse response filter from a measured input value that is a measured value of an input to a subject to control and a measured output value that is a measured value of an output from the subject to control, determining, based on the first coefficient, a second coefficient configuring an infinite impulse response filter, and identifying an inverse system that is a system including the second coefficient and a part of the first coefficient and configured to identify a target value of the input from a target value of the output from the subject to control; and estimating an input value to be input to the subject to control from a weighted sum of the target value of the output set in accordance with a time, based on the inverse system.

According to an aspect of the present disclosure, a program causes a computer of a compensator to perform processing for identifying a first coefficient configuring a finite impulse response filter from a measured input value that is a measured value of an input to a subject to control and a measured output value that is a measured value of an output from the subject to control, processing for determining, based on the first coefficient, a second coefficient configuring an infinite impulse response filter, and identifying an inverse system that is a system including the second coefficient and a part of the first coefficient and configured to identify a target value of the input from a target value of the output from the subject to control, and processing for estimating an input value to be input to the subject to control from a weighted sum of the target value of the output set in accordance with a time, based on the inverse system.

According to an aspect of the present disclosure, a compensator includes a processor, and a storage device connected to the processor and configured to store a measured input value that is a measured value of an input to a subject to control, and a measured output value that is a measured value of an output from the subject to control. The processor performs processing for identifying, from the measured input value and the measured output value, a first coefficient configuring a finite impulse response filter, processing for determining, based on the first coefficient, a second coefficient configuring an infinite impulse response filter so that a transfer function has a numerator of g₁z⁻¹ and a denominator polynomial of 1−h₁z⁻¹, −h₂z⁻²−h₃z⁻³− . . . , and identifying an inverse system, including the second coefficient and a part of the first coefficient, for the subject to control, and processing for estimating an input value to be input to the subject to control from a weighted sum of a time history of a target value, which will be described later, based on the inverse system. According to an aspect of the present disclosure, with a time history of a target value, based on a difference between a calculated value of an ideal output obtained in a case in which there is no disturbance or characteristics variation with respect to a subject to control and an actual output of the subject to control, a target reference value is updated using a target reference value updating device at a cycle at least twice as long as an updating cycle of a control input, then the target reference value is input to a reference model, and a target value that is interpolated so that the target reference value updated at the longer cycle is aligned with the updating cycle of the control input is generated. Then, the target value is input to the compensator, and processing for estimating an input value to be input to the subject to control is performed.

According to an aspect of the present disclosure, a compensator includes a processor, and a storage device connected to the processor and configured to store a measured input value that is a measured value of an input to a subject to control, and a measured output value that is a measured value of an output from the subject to control. The processor performs processing for identifying, from the measured input value and the measured output value, a first coefficient configuring a finite impulse response filter, processing for determining, based on the first coefficient, a second coefficient configuring an infinite impulse response filter so that a transfer function has a numerator of g₁z⁻¹ and a denominator polynomial of 1−h₁z⁻¹, −h₂z⁻²−h₃z⁻³− . . . , and identifying an inverse system, including the second coefficient and a part of the first coefficient, for the subject to control, and processing for estimating an input value to be input to the subject to control from a weighted sum of a time history of a target value of the output, based on the inverse system.

According to a compensator, a control system, a compensation method, and a program according to the present disclosure, an input value to be input to a subject to control can be accurately calculated from a small amount of data.

### BRIEF DESCRIPTION OF DRAWINGS

The disclosure will be described with reference to the accompanying drawings, wherein like numbers reference like elements.

FIG. 1 is a diagram illustrating a functional configuration of a control system according to a first embodiment of the present disclosure.

FIG. 2 is a diagram illustrating a functional configuration of the control system according to a second embodiment of the present disclosure.

FIG. 3 is a diagram illustrating a functional configuration of the control system according to a third embodiment of the present disclosure.

FIG. 4 is a diagram illustrating a functional configuration of the control system according to a fourth embodiment of the present disclosure.

FIG. 5 is a diagram illustrating a functional configuration of the control system according to a fifth embodiment of the present disclosure.

FIG. 6 is a diagram illustrating a functional configuration of the control system according to a sixth embodiment of the present disclosure.

FIG. 7 is a diagram illustrating a functional configuration of the control system according to a seventh embodiment of the present disclosure.

FIG. 8 is a diagram illustrating an example of a hardware configuration of a compensator according to at least one of the embodiments of the present disclosure.

### DESCRIPTION OF EMBODIMENTS

### First Embodiment

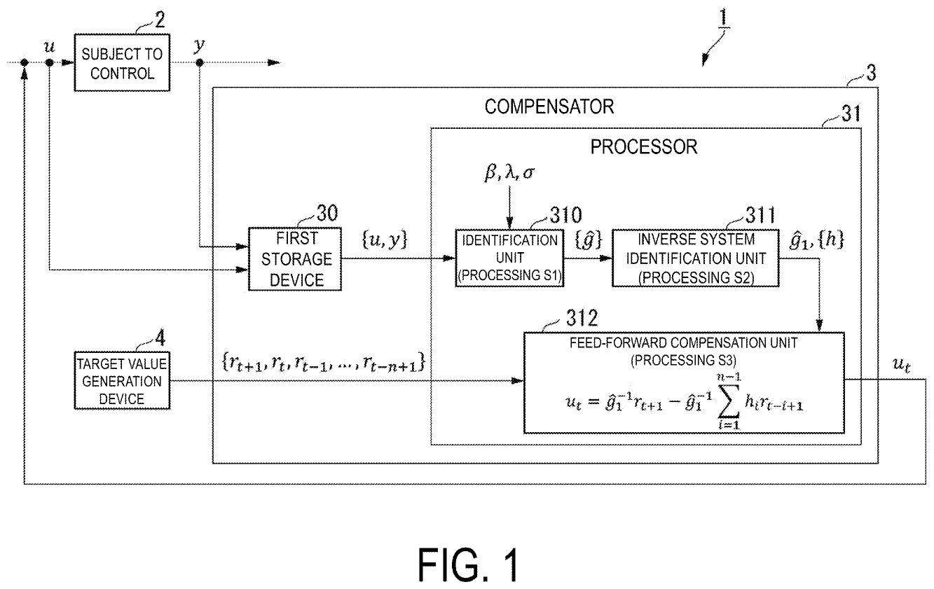

A control system 1 according to a first embodiment of the present disclosure will be described below with reference to FIG. 1.

### Functional Configuration of Control System

FIG. 1 is a diagram illustrating a functional configuration of the control system according to the first embodiment of the present disclosure.

As illustrated in FIG. 1, the control system 1 includes a compensator 3 that calculates an input value to be input to a subject to control 2, and a target value generation device 4 that generates a target value of an output of the subject to control 2.

The compensator 3 is configured by a computer, such as a server or a personal computer, and includes a first storage device 30 (a storage device) and a processor 31.

The first storage device 30 is connected to the processor 31, and stores measured values of the input (hereinafter, referred to as “measured input values u”) and measured values of the output (hereinafter, referred to as “measured output values y”), which are received from the subject to control 2 at a predetermined cycle.

The processor 31 controls the entire operation of the compensator 3. The processor 31 operates in accordance with a predetermined program, and functions as an identification unit 310, an inverse system identification unit 311, and a feed-forward compensation unit 312.

The identification unit 310 performs processing S1 for identifying, from the measured input values u and the measured output values y, a first coefficient g configuring a finite impulse response filter (FIR filter).

The inverse system identification unit 311 performs processing S2 for determining a second coefficient h configuring an infinite impulse response filter (IIR filter), based on the first coefficient g, and identifying an inverse system for the subject to control 2, the inverse system including the second coefficient h and a part of the first coefficient g. The inverse system is a model for determining a target value of the input from the target value of the output of the subject to control 2. In other words, the inverse system identification unit 311 identifies the model for which the target value of the input is determined from the target value of the output.

The feed-forward compensation unit 312 performs processing S3 for calculating and estimating an input to be input to the subject to control 2 from a weighted sum of a time history of the target values of the output, based on the inverse system.

### Processing Flow of Compensator

Here, a specific processing flow in each of the units of the compensator 3 according to the present embodiment will be described. First, the identification unit 310 of the compensator 3 performs the processing S1 for identifying the first coefficient g configuring the FIR filter, by using a kernel-type system identification method. In the kernel-type system identification, an impulse response of the subject to control 2 is identified by Bayes estimation in the following manner.

When the measured input values of the subject to control 2 are uᵢ (i=t, t−1, t−2, . . . ) and the measured output values are yᵢ (i=t, t−1, t−2, . . . ), the output of the subject to control 2 is expressed in the FIR filter format as in Equation (3) below.

$$\begin{matrix}[ Equation 3 ] & \\ {y}_{t + 1} = {\sum }_{i = 1}^{n} {g}_{i} {u}_{t - i + 1} + N ( 0 , {σ}^{2} ) , \\ {\hat{y}}_{t + 1} = {\sum }_{i = 1}^{n} {g}_{i} {u}_{t - i + 1} & ( 3 )\end{matrix}$$

In Equation (3) above, the measured output values y of the subject to control 2 are expressed by a sum of weighted moving averages of the measured input values u and observation noise. Weighting coefficients (the first coefficients) of the weighted moving averages are {g₁, g₂, . . . , gₙ}. These weighting coefficients correspond to the impulse response of the subject to control 2. The observation noise is zero on average, and the standard deviation is expressed by the Gaussian distribution of σ. “\hat{ }yₜ” (corresponding to a notation obtained by attaching a hat symbol to “yₜ”, which will be hereinafter used in the same manner) is an estimated value of yₜ.

In a prediction model using the FIR filter, values of the weighting coefficients {g₁, g₂, . . . , gₙ} of the measured input values u in Equation (3) are determined based on the actual measured input values u and the actual measured output values y. In the kernel-type system identification, the values of {g₁, g₂, . . . , gₙ} are determined by introducing an average of 0 and a prior distribution of covariance K (n×n) to the weighting coefficients {g₁, g₂, . . . , gₙ}. This K is referred to as a kernel, and prior information regarding the subject to control 2 is incorporated therein. For example, in a primary stable spline kernel, prior knowledge indicating that the impulse response of the subject to control 2 converges exponentially is incorporated therein. When the primary stable spline kernel is used, an i-row j-column element of K is given by Equation (4) below.

[Equation 4]

[K]_{i,j}=λβ^{max{i,j}},λ>0,0<β<1,(i=1,2, . . . ,n;j=1,2, . . . ,n) (4)

Here, λ and β are parameters for tuning the kernel K, and the parameters λ and β, which are preset in accordance with system characteristics of the subject to control 2, are given to the identification unit 310. Note that, when the values of λ and β are unknown, a plurality of combinations of the values may be prepared in advance, computation to be described below may be performed on each of the combinations, and results of the combination having the smallest error (error variance, for example) between the measured output value y and the estimated value “\hat{ }y” of the model may be used as the values.

In order to simplify the notation, the vector representation illustrated in Equation (5) below is introduced. In Equation (5), N is the number of observation points.

$$\begin{matrix}[ Equation 5 ] & \\ U = [ \begin{matrix}{u}_{0} & 0 & & … & 0 \\ {u}_{1} & {u}_{0} & 0 & & 0 \\ ⋮ & ⋮ & ⋱ & & ⋮ \\ {u}_{N - 2} & {u}_{N - 3} & … & & {u}_{N - n - 1} \\ {u}_{N - 1} & {u}_{N - 2} & … & … & {u}_{N - n}\end{matrix} ] , Y = [ \begin{matrix}{y}_{1} \\ {y}_{2} \\ ⋮ \\ {y}_{N - 1} \\ {y}_{N}\end{matrix} ] & ( 5 )\end{matrix}$$

Using these equations, a posterior distribution of the weighting coefficients g results in a Gaussian distribution in which the covariance is expressed by Equation (6) and the average is expressed by Equation (7).

$$\begin{matrix}[ Equation 6 ] & \\ \hat{K} = {K ( I + \frac{1}{{σ}^{2}} {U}^{T} UK )}^{- 1} & ( 6 ) \\ [ Equation 7 ] & \\ \hat{g} = \frac{1}{{σ}^{2}} \hat{K} Y & ( 7 )\end{matrix}$$

“\hat{ }g” in equation (7) (corresponding to a notation obtained by attaching a hat symbol to “g”, which will be hereinafter used in the same manner) is an estimated value of the weighting coefficient g. The identification unit 310 identifies the value of the estimated “\hat{ }g” as a constant of the model.

An advantage of the above-described kernel-type system identification method is that the prediction model is obtained using a small number of data points N. In a general method, when a number n of the constants of the prediction model is approximately 30, the number of data points needs to be approximately 2000. In contrast, the above-described kernel-type system identification method has an advantage in that identification can be performed with only approximately 100 data points N.

Next, the inverse system identification unit 311 performs the processing S2 for identifying the inverse system for the subject to control 2. As described above, it is assumed that the model for the subject to control 2 is expressed by Equation (8) or Equation (8A) below, using the FIR filter.

$$\begin{matrix}[ Equation 8 ] & \\ {\hat{y}}_{t + 1} = {\sum }_{i = 1}^{n} {g}_{i} {u}_{t - i + 1} , ( {u}_{0} = {u}_{- 1} = {u}_{- 2} = … = 0 , t = 1 , 2 , 3 , … ) & ( 8 ) \\ [ Equation 8 A ] & \\ \hat{y} = \frac{{g}_{1} {z}^{- 1} + {g}_{2} {z}^{- 2} + … + {g}_{n} {z}^{- n}}{1} u & ( 8 A )\end{matrix}$$

First, the inverse system identification unit 311 converts the FIR filter of Equation (8) expressing the subject to control 2 into the IIR filter of a special format illustrated in Equation (9) below. Equation (9) can also be expressed as Equation (9A).

$$\begin{matrix} [ Equation 9 ] & \\ {\hat{y}}_{t} = {g}_{1} {u}_{t - 1} + {\sum }_{i = 1}^{n} {h}_{i} {y}_{t - i} , ( {y}_{0} = {y}_{- 1} = {y}_{- 2} = … = 0 , t = 1 , 2 , 3 , … ) & ( 9 ) \\ [ Equation 9 A ] & \\ \hat{y} = \frac{{g}_{1} {z}^{- 1}}{1 - {h}_{1} {z}^{- 1} - {h}_{2} {z}^{- 2} - … - {h}_{n - 1} {z}^{- n + 1}} u & ( 9 A )\end{matrix}$$

In Equation (9) above, g₁ is a part of the already determined FIR filter. {h₁, h₂, . . . , hₙ₋₁} are coefficients (second coefficients) that are parameters of the IIR filter, and are determined by solving the simultaneous linear equations of Equation (10) below.

$$\begin{matrix}[ Equation 10 ] & \\ [ \begin{matrix}{g}_{2} \\ {g}_{3} \\ ⋮ \\ {g}_{n - 1} \\ {g}_{n}\end{matrix} ] = [ \begin{matrix}{g}_{1} & 0 & 0 & … & 0 \\ {g}_{2} & {g}_{1} & 0 & … & 0 \\ ⋮ & ⋮ & ⋱ & & ⋮ \\ {g}_{n - 2} & {g}_{n - 3} & … & {g}_{1} & 0 \\ {g}_{n - 1} & {g}_{n - 2} & … & {g}_{2} & {g}_{1}\end{matrix} ] [ \begin{matrix}{h}_{1} \\ {h}_{2} \\ ⋮ \\ {h}_{n - 2} \\ {h}_{n - 1}\end{matrix} ] & ( 10 )\end{matrix}$$

Further, when the IIR filter is vectorized, the IIR filter is expressed as in Equation (11) below.

$$\begin{matrix}[ Equation 11 ] & \\ {\hat{y}}_{t} = {g}_{1} {u}_{t - 1} + [ \begin{matrix}{h}_{1} & {h}_{2} & {h}_{3} & …\end{matrix} ] [ \begin{matrix}{y}_{t - 1} \\ {y}_{t - 2} \\ {y}_{t - 3} \\ ⋮\end{matrix} ] & ( 11 )\end{matrix}$$

An impulse response {g} to the input is an example of an actual value of an output {y}. Thus, Equation (11) above needs to hold even when {y₀, y₁, y₂, . . . , yₙ} are rewritten as {0, g₁, g₂, . . . , gₙ} and {uᵢ, u₂, . . . , uₙ} are rewritten as unit impulses {1, 0, 0, . . . , 0}. As a result, for example, g2 may be written as in Equation (12), and similarly, g3 may be written as in Equation (13).

$$\begin{matrix}[ Equation 12 ] & \\ {g}_{2} = [ \begin{matrix}{h}_{1} & 0 & 0 & …\end{matrix} ] [ \begin{matrix}{g}_{1} \\ {g}_{2} \\ {g}_{3} \\ ⋮\end{matrix} ] & ( 12 ) \\ [ Equation 13 ] & \\ {g}_{3} = [ \begin{matrix}{h}_{2} & {h}_{1} & 0 & …\end{matrix} ] [ \begin{matrix}{g}_{1} \\ {g}_{2} \\ {g}_{3} \\ ⋮\end{matrix} ] & ( 13 )\end{matrix}$$

When this is expressed in matrix form, Equation (14) below is obtained, and the simultaneous linear equations of Equation (10) above, in which {h} is an unknown number, are obtained.

$$\begin{matrix}[ Equation 14 ] & \\ [ \begin{matrix}{g}_{2} \\ {g}_{3} \\ ⋮ \\ {g}_{n - 1} \\ {g}_{n}\end{matrix} ] = \\ [ \begin{matrix}{h}_{1} & 0 & 0 & … & 0 \\ {h}_{2} & {h}_{1} & 0 & … & 0 \\ ⋮ & ⋮ & ⋱ & & ⋮ \\ {h}_{n - 2} & {h}_{n - 3} & … & {h}_{1} & 0 \\ {h}_{n - 1} & {h}_{n - 2} & … & {h}_{2} & {h}_{1}\end{matrix} ] [ \begin{matrix}{g}_{1} \\ {g}_{2} \\ ⋮ \\ {g}_{n - 2} \\ {g}_{n - 1}\end{matrix} ] = [ \begin{matrix}{h}_{1} \\ {h}_{2} \\ ⋮ \\ {h}_{n - 2} \\ {h}_{n - 1}\end{matrix} ] {g}_{1} + [ \begin{matrix}0 \\ {h}_{1} \\ ⋮ \\ {h}_{n - 3} \\ {h}_{n - 2}\end{matrix} ] {g}_{2} + … + [ \begin{matrix}0 \\ 0 \\ ⋮ \\ {h}_{1} \\ {h}_{2}\end{matrix} ] {g}_{n - 2} + [ \begin{matrix}0 \\ 0 \\ ⋮ \\ 0 \\ {h}_{1}\end{matrix} ] {g}_{n - 1} = \\ [ \begin{matrix}{g}_{1} \\ {g}_{2} \\ ⋮ \\ {g}_{n - 2} \\ {g}_{n - 1}\end{matrix} ] {h}_{1} + [ \begin{matrix}0 \\ {g}_{1} \\ ⋮ \\ {g}_{n - 3} \\ {g}_{n - 2}\end{matrix} ] {h}_{2} + … + [ \begin{matrix}0 \\ 0 \\ ⋮ \\ {g}_{1} \\ {g}_{2}\end{matrix} ] {h}_{n - 2} + [ \begin{matrix}0 \\ 0 \\ ⋮ \\ 0 \\ {g}_{1}\end{matrix} ] {h}_{n - 1} = [ \begin{matrix}{g}_{1} & 0 & 0 & … & 0 \\ {g}_{2} & {g}_{1} & 0 & … & 0 \\ ⋮ & ⋮ & ⋱ & & ⋮ \\ {g}_{n - 2} & {g}_{n - 3} & … & {g}_{1} & 0 \\ {g}_{n - 1} & {g}_{n - 2} & … & {g}_{2} & {g}_{1}\end{matrix} ] [ \begin{matrix}{h}_{1} \\ {h}_{2} \\ ⋮ \\ {h}_{n - 2} \\ {h}_{n - 1}\end{matrix} ] & ( 14 )\end{matrix}$$

In this way, the inverse system identification unit 311 can identify the inverse system expressed by Equation (15) below.

$$\begin{matrix}[ Equation 15 ] & \\ {u}_{t - 1} = {g}_{1}^{- 1} [ {y}_{t} - {\sum }_{i = 1}^{n - 1} {h}_{i} {y}_{t - i} ] & ( 15 )\end{matrix}$$

Next, the feed-forward compensation unit 312 performs the processing S3 for calculating an input value uₜ to be input to the subject to control 2 at a time t. Here, the feed-forward compensation unit 312 calculates and estimates the input value uₜ to be input at the time t by using Equation (16), which is based on the inverse system, in order to achieve a target value rₜ₊₁ at a time t+1, which is a future time one step later than the time t.

$$\begin{matrix}[ Equation 16 ] & \\ {u}_{t} = {g}_{1}^{- 1} [ {r}_{t + 1} - {\sum }_{i = 1}^{n - 1} {h}_{i} {r}_{t - i + 1} ] & ( 16 )\end{matrix}$$

Here, {rₜ₊₁, rₜ, rₜ₋₁, . . . , rₜ₋ₙ} are target values of output set according to a time, that is, the time history of the target values of the output acquired from the target value generation device 4. In this way, the feed-forward compensation unit 312 determines the input value uₜ based on the weighted sum of the time history of the target values. Specifically, the target value is a given value for the subject to control 2 and the compensator 3, such as a planned trajectory of cutting in a machine tool, a planned trajectory of a moving body such as an aircraft, and a planned power generating capacity in a power generation plant.

Note that estimation processing (the processing S3) of the input value uₜ by the feed-forward compensation unit 312 is performed at any time, but estimation and updating processing (the processing S1) of the constant (“\hat{ }g”) of the model by the identification unit 310 is performed at a predetermined cycle (every 10 minutes, for example). This predetermined cycle may be arbitrarily changed in accordance with the system characteristics of the subject to control. In this way, the compensator 3 can periodically reflect changes in the characteristics of the subject to control 2 in the prediction model.

### Operational Effects

As described above, the compensator 3 according to the present embodiment performs the processing S1 for identifying the first coefficient g configuring the FIR filter, based on the measured input values u and the measured output values y, the processing S2 for determining the second coefficient g configuring the IIR filter based on the first coefficient g, and identifying the inverse system for the subject to control 2 including the second coefficient g and the part (g₁) of the first coefficient g, and the processing S3 for estimating and compensating for the input value uₜ to be input to the subject to control 2 from the weighted sum of the time history of the target values r of the output, based on the inverse system.

As a result, by using the kernel-type system identification method to identify the first coefficient g configuring the FIR filter, the compensator 3 can update the model for the subject to control 2 with a smaller number of the data points than that of a known system. Further, the compensator 3 according to the present embodiment solves a problem of the divergence of numerical calculation that occurs when expressing the model for the subject to control 2 using a known IIR filter. In the compensator 3 according to the present embodiment, since the model for the subject to control 2 is expressed by the IIR filter of the special format as in Equation (9), the inverse system for the subject to control 2 can be calculated by the FIR filter as in Equation (8). As a result, the input value uₜ is calculated by the weighted sum of the time history of the target values r, and the divergence of numerical calculation can thus be avoided. Therefore, the compensator 3 can accurately calculate the input value uₜ to be input to the subject to control 2 from a small amount of data.

### Second Embodiment

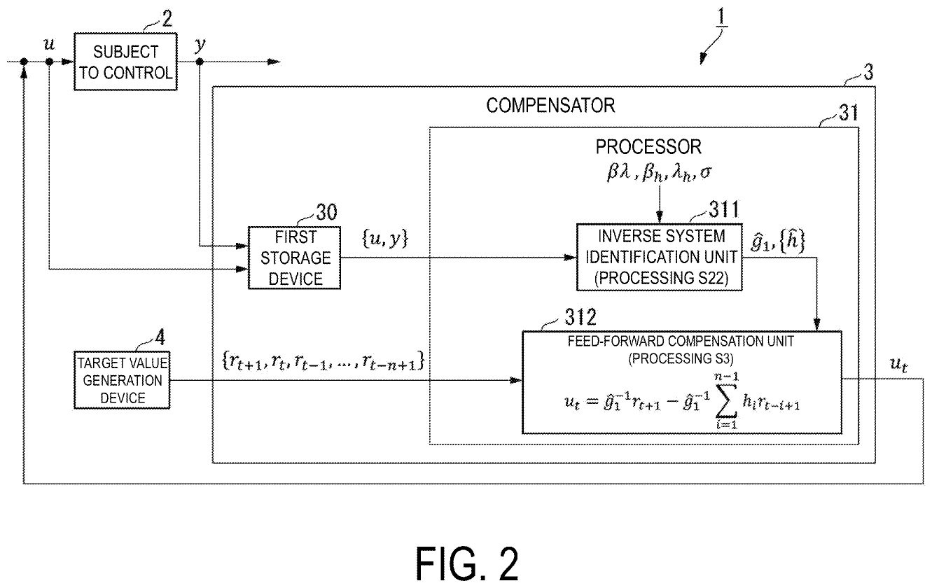

Next, the control system 1 according to a second embodiment of the present disclosure will be described with reference to FIG. 2.

The same components as those of the first embodiment will be denoted by the same reference signs, and a detailed description thereof will be omitted.

### Functional Configuration of Control System

FIG. 2 is a diagram illustrating a functional configuration of the control system according to the second embodiment of the present disclosure.

The compensator 3 according to the first embodiment first derives, in the identification unit 310, the prediction model by the FIR filter, and then in the inverse system identification unit 311, converts the prediction model to the prediction model by the IIR filter. Thus, in the compensator 3 according to the first embodiment, two steps (the processing S1 and the processing S2) are required. In contrast, as illustrated in FIG. 2, the compensator 3 according to the present embodiment is characterized in that the prediction model by the IIR filter is directly derived in the inverse system identification unit 311. Thus, in the compensator 3 according to the present embodiment, the identification unit 310 may be omitted.

### Processing Flow of Compensator

A specific processing flow of the compensator 3 according to the present embodiment will be described. In place of the processing S1 to S2 of the first embodiment, the compensator 3 according to the present embodiment acquires the first coefficient g and the second coefficient h configuring the IIR filter, and performs processing S22 for identifying the inverse system for the subject to control 2. In the processing S22, the inverse system identification unit 311 first models the subject to control 2 as described below. The infinite impulse response filter of Equation (17) may also be expressed as a transfer function having the denominator polynomial of 1−h₁z⁻¹−h₂z⁻²−h₃z⁻³− . . . and a numerator of g₁z⁻¹, as in Equation (17A).

$$\begin{matrix} [ Equation 17 ] & \\ {y}_{t + 1} = {g}_{1} {u}_{t} + {\sum }_{i = 1}^{n - 1} {h}_{i} {y}_{t - i + 1} + N ( 0 , {σ}^{2} ) , {\hat{y}}_{t + 1} = {g}_{1} {u}_{t} {\sum }_{i = 1}^{n - 1} {h}_{i} {y}_{t - i + 1} & ( 17 ) \\ [ Equation 17 A ] & \\ \hat{y} = \frac{{g}_{1} {z}^{- 1}}{1 - {h}_{1} {z}^{- 1} - {h}_{2} {z}^{- 2} - … - {h}_{n} {z}^{- n + 1}} u & ( 17 A )\end{matrix}$$

A difference from the FIR model identification (the processing S1) according to the first embodiment is that historical values of the measured output values y are used for the prediction. Accordingly, the second coefficients {h₁, h₂, . . . , hₙ₋₁} for the historical values of the measured output values y become a subject to be identified. Further, in this case, the coefficient of the measured input value u is only g₁. When these are reflected, the primary stable spline kernel is expressed as in Equation 18 below.

$$\begin{matrix}[ Equation 18 ] & \\ {K}_{gh} = [ \begin{matrix}{K}_{g} & 0 \\ 0 & {K}_{h}\end{matrix} ] & ( 18 )\end{matrix}$$

Further, elements K_{g} and Kₕ, which are elements of a primary stable spline kernel K_{gh}, are expressed as in Equations 19 and 20, respectively.

[Equation 19]

[K_{g}]_{1,1}=λβ,λ>0,0<β<1 (19)

[Equation 20]

[Kₕ]_{i,j}=λₕβₕ^{max{i,j}},λₕ>0,0<βₕ<1,(i=1,2, . . . ,n;j=1,2,n) (20)

Furthermore, when a vector representation according to Equation (21) below is introduced, a posterior distribution of the model constant [g₁, h^{T}]^{T} results in a Gaussian distribution having a covariance expressed by Equation (22) and an average expressed by Equation (23).

$$\begin{matrix}[ Equation 21 ] & \\ X = [ \begin{matrix}{u}_{0} & {y}_{0} & 0 & & … & 0 \\ {u}_{1} & {y}_{1} & {y}_{0} & 0 & & 0 \\ ⋮ & ⋮ & ⋮ & ⋱ & & ⋮ \\ {u}_{N - 2} & {y}_{N - 2} & {y}_{N - 3} & … & & {y}_{N - n - 1} \\ {u}_{N - 1} & {y}_{N - 1} & {y}_{N - 2} & … & … & {y}_{N - n}\end{matrix} ] , Y = [ \begin{matrix}{y}_{1} \\ {y}_{2} \\ ⋮ \\ {y}_{N - 1} \\ {y}_{N}\end{matrix} ] & ( 21 ) \\ [ Equation 22 ] & \\ {\hat{K}}_{gh} = {{K}_{gh} ( I + \frac{1}{{σ}^{2}} {X}^{T} {XK}_{gh} )}^{- 1} & ( 22 ) \\ [ Equation 23 ] & \\ [ \begin{matrix}{\hat{g}}_{1} \\ \hat{h}\end{matrix} ] = \frac{1}{{σ}^{2}} {\hat{K}}_{gh} Y & ( 23 )\end{matrix}$$

The values of “\hat{ }g₁” and “\hat{ }h” (corresponding to a notation obtained by attaching a hat symbol to “h”, which will be hereinafter used in the same manner) are respectively used as a first coefficient g₁ and the second coefficient h of the prediction model by the IIR filter. That is, the feed-forward compensation unit 312 performs the processing S3 for calculating and estimating the input value uₜ to be input at the time t, based on those coefficients g₁ and h and the inverse system expressed by Equation (16) of the first embodiment.

### Operational Effects

As described above, the compensator 3 according to the present embodiment determines, from the measured input values u and the measured output values y, the first coefficient g and the second coefficient h configuring the IIR filter of the special format shown in Equation (9), and performs the processing S22 for identifying the inverse system for the subject to control 2 including the second coefficient h and a part (g₁) of the first coefficient g.

In this way, the compensator 3 can directly derive the prediction model by the IIR filter of the special format shown in Equation (9), without performing the processing for deriving the prediction model by the FIR filter (the processing S1 of the identification unit 310). As a result, the compensator 3 can use a simplified series of processes for determining the input value uₜ.

### Third Embodiment

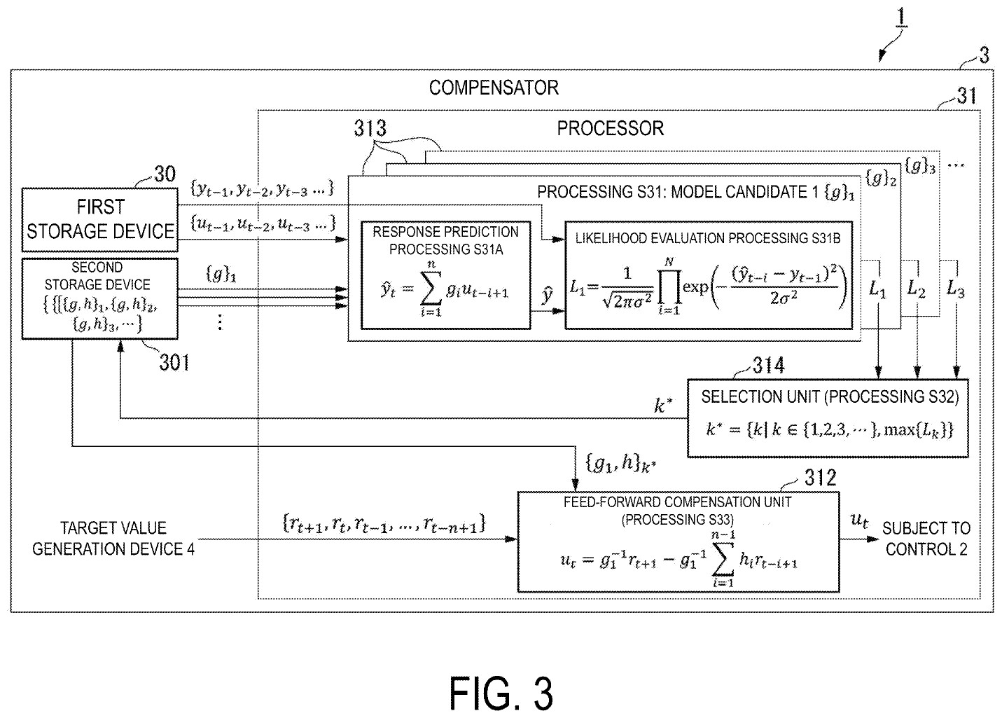

Next, the control system 1 according to a third embodiment of the present disclosure will be described with reference to FIG. 3.

The same components as those in the above-described embodiments will be denoted by the same reference signs, and a detailed description thereof will be omitted.

### Functional Configuration of Control System

FIG. 3 is a diagram illustrating a functional configuration of the control system according to the third embodiment of the present disclosure.

The compensators 3 according to the first embodiment and the second embodiment identify the model for the subject to control 2 in real time, in parallel with the feed-forward compensation of the subject to control 2. However, performing real-time computation for model identification is not preferable for reasons such as a high computation load, the fact that it is not possible to inspect in advance whether the feed-forward compensator (the inverse system) derived in parallel is good, and the like. In order to solve this problem, the processor 31 of the compensator 3 according to the present embodiment functions as a likelihood estimation unit 313, a selection unit 314, and the feed-forward compensation unit 312, as illustrated in FIG. 3. Note that the function of the feed-forward compensation unit 312 is partially the same as that of the first embodiment. Here, only functions that are different from those of the above-described embodiments will be described.

The likelihood estimation unit 313 performs processing S31 for estimating a likelihood of each of a plurality of model candidates based on the measured output values y, and the estimated value “\hat{ }y” of the output obtained from the first coefficient g and the measured input values u.

The selection unit 314 performs processing S32 for selecting the model candidate having the highest estimated likelihood.

The feed-forward compensation unit 312 performs processing S33 for calculating the input value uₜ to be input to the subject to control 2 from the weighted sum of the time history of the target values r of the output, based on the inverse system corresponding to the selected model candidate.

In addition, the compensator 3 according to the present embodiment further includes a second storage device 301 (a storage device). The second storage device 301 stores in advance a plurality of the first coefficients g configuring each of the plurality of model candidates for the subject to control 2, and the inverse system corresponding to each of the plurality of model candidates.

### Processing Flow of Compensator

A specific processing flow of the compensator 3 according to the present embodiment will be described.

First, pairs of each of the plurality of model candidates created over a range, over which dynamic characteristics of the subject to control 2 are assumed to change, and the inverse system (the feed-forward compensator) for each of the plurality of model candidates are stored in advance in the second storage device 301. The model candidates are created by changing an operation condition of the subject to control 2, and are each a candidate for the prediction model by the FIR filter. When the subject to control is a power generation plant, the operating condition is, for example, an output of the power generation plant. In this case, model candidates 1, 2, 3, . . . are created for each of outputs (outputs 100%, 90%, 80%, . . . , for example) of the power generation plant. Further, for each of the model candidates, the inverse system is calculated in advance. In this case, the inverse system includes the first coefficient g and the second coefficient h, which have been calculated based on the measured input values u and the measured output values y. Combinations of the model candidates 1, 2, 3, . . . and the inverse systems {{g, h}₁, {g, h}₂, {g, h}₃, . . . } are stored in advance in the second storage device 301. Note that when the subject to control is a machine tool, the operation condition may be a movement speed of the machine, a jig arrangement, or the like.

Further, in real time, the likelihood estimation unit 313 performs the processing S31 for estimating the likelihood of the model candidate for each of the model candidates stored in the second storage device 301. Specifically, first, the likelihood estimation unit 313 performs response prediction processing S31A for determining the estimated output value “\hat{ }y” of the subject to control 2, using the first coefficient g of each of the model candidates and the measured input values u. For example, as illustrated in FIG. 3, the likelihood estimation unit 313 estimates the estimated output value “\hat{ }y” of the model candidate 1, using a first coefficient {g}₁ of the model candidate 1 stored in advance in the second storage device 301 and the measured input values u accumulated in the first storage device 30. At this time, the likelihood estimation unit 313 may estimate estimated output values “\hat{ }yₜ₋₁”, “\hat{ }yₜ₋₂”, and “\hat{ }yₜ₋₃”, . . . corresponding to each of a plurality of times t−1, t−2, t−3, . . . and so on. Similarly, the likelihood estimation unit 313 estimates the estimated output value “\hat{ }y” for each of the model candidates 2, 3, . . . and so on.

Next, the likelihood estimation unit 313 performs likelihood evaluation processing S31B for estimating a likelihood L1 of the model candidate 1 based on the estimated output value “\hat{ }y” and the measured output values y accumulated in the first storage device 30. The estimation of the likelihood is determined by a simple computation, for example, while taking into account measurement noise and the like and assuming that differences between the estimated output value “\hat{ }y” and the measured output values y are expressed by the Gaussian distribution. For example, the likelihood L1 is estimated using Equation (24) below. Similarly, the likelihood estimation unit 313 estimates likelihoods L2, L3, . . . for the model candidates 2, 3, . . . , respectively.

$$\begin{matrix}[ Equation 24 ] & \\ {L}_{1} = \frac{1}{\sqrt{2 {πσ}^{2}}} {\prod }_{i = 1}^{N} exp ( - \frac{{( {\hat{y}}_{t - i} - {y}_{t - 1} )}^{2}}{2 {σ}^{2}} ) & ( 24 )\end{matrix}$$

Next, the selection unit 314 performs the processing S32 for selecting the model candidate having the highest likelihood among the model candidates 1, 2, 3 . . . , that is, the model candidate having the estimated output value “\hat{ }y” closest to the measured output value y, which is an actual measured value.

Next, the feed-forward compensation unit 312 performs the processing S33 for calculating and estimating the input value uₜ by using the inverse system paired up with the model candidate selected by the selection unit 314. The processing for calculating and estimating the input value uₜ is the same as the processing S3 of the first embodiment.

### Operational Effects

As described above, the compensator 3 according to the present embodiment performs the processing S31 for estimating the likelihood of each of the plurality of inverse systems based on the measured output values y, and the estimated value “\hat{ }y” of the output, which is obtained from the inverse system and the measured input values u stored in advance in the second storage device 301, the processing S32 for selecting the inverse system having the highest estimated likelihood among the plurality of inverse systems, and the processing S33 for calculating the input value uₜ to be input to the subject to control 2 from the weighted sum of the time history of the output target values r, based on the selected inverse system.

In this way, the compensator 3 does not perform real-time computation for the identification, and thus, the computation load can be reduced. Further, since the compensator 3 creates the inverse system in advance, it is possible to inspect in advance whether the inverse system is good.

### Fourth Embodiment

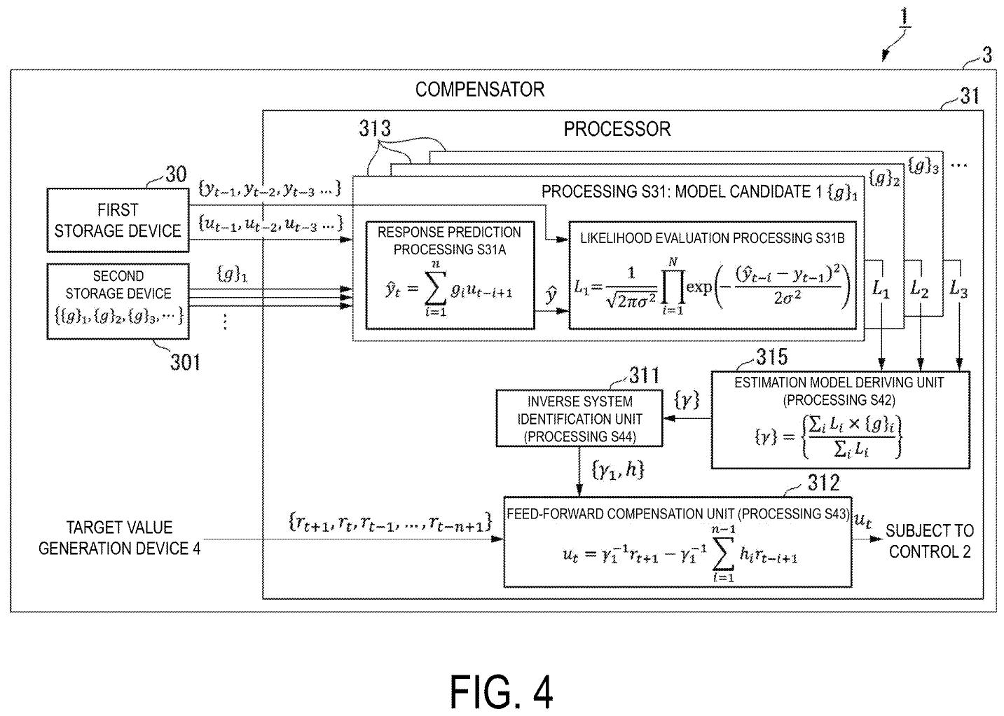

Next, the control system 1 according to a fourth embodiment of the present disclosure will be described with reference to FIG. 4.

The same components as those in the above-described embodiments will be denoted by the same reference signs, and a detailed description thereof will be omitted.

### Functional Configuration of Control System

FIG. 4 is a diagram illustrating a functional configuration of the control system according to the fourth embodiment of the present disclosure.

In the third embodiment described above, only one of the model candidates having the highest likelihood is selected from a group of the plurality of model candidates, and the input value uₜ of the subject to control is calculated using the inverse system corresponding to the selected model candidate. This method does not have any problem when the likelihood of the selected model candidate is overwhelmingly high compared to those of the other model candidates. However, for example, when two of the model candidates have likelihoods overwhelmingly higher than those of the other model candidates, respectively, and when those two likelihoods are extremely close to each other, there is a possibility that an error may occur with respect to the subject to control 2, with whichever of the two candidates is selected. In such a case, it is assumed that the subject to control 2 is in an intermediate state between the two model candidates, and it is desirable to perform effective control for the intermediate state.

Thus, the processor 31 of the compensator 3 according to the present embodiment functions as the likelihood estimation unit 313, an estimation model deriving unit 315, the inverse system identification unit 311, and the feed-forward compensation unit 312. Note that the function of the likelihood estimation unit 313 is the same as that of the third embodiment. Further, the functions of the inverse system identification unit 311 and the feed-forward compensation unit 312 are partially the same as those of the first embodiment. Here, only the functions that are different from those of the above-described embodiments will be described.

The estimation model deriving unit 315 performs processing S42 for deriving a third coefficient γ, which is a weighted average of the first coefficients g of each of the model candidates, using the likelihood estimated by the likelihood estimation unit 313 as a weighting factor.

The inverse system identification unit 311 performs processing S44 for determining the second coefficient h configuring the IIR filter based on the third coefficient γ, and identifying the inverse system for the subject to control 2, the inverse system including the second coefficient h and a part (γ₁) of the third coefficient γ.

The feed-forward compensation unit 312 performs, based on the inverse system identified by the inverse system identification unit 311, processing S43 for estimating the input value uₜ to be input to the subject to control 2 from the weighted sum of the time history of the target values r of the output.

Further, the second storage device 301 according to the present embodiment stores in advance the plurality of first coefficients {{g}₁, {g}₂, {g}₃, . . . } configuring each of the plurality of model candidates for the subject to control 2.

### Processing Flow of Compensator

First, the plurality of model candidates created over the range, over which the dynamic characteristics of the subject to control 2 are assumed to change, are stored in advance in the second storage device 301. In the same manner as in the third embodiment, the model candidates are created by changing the operation condition of the subject to control 2, and are each a candidate for the prediction model by the FIR filter. The second storage device 301 stores in advance the plurality of first coefficients {{g}₁, {g}₂, {g}₃, . . . }configuring each of the plurality of model candidates for the subject to control 2.

Further, in real time, the likelihood estimation unit 313 performs the processing S31 for estimating the likelihoods L1, L2, L3, . . . for the plurality of model candidates 1, 2, 3, . . . , respectively, in the same manner as in the third embodiment.

Next, the estimation model deriving unit 315 performs the processing S42 for deriving a weighted average of the model candidates as an estimation model (the third coefficient γ), using the likelihoods L1, L2, L3, . . . estimated by the likelihood estimation unit 313 as the weighting factor for each of the model candidates. Note that since the model candidate retains the model in the FIR filter format, it is sufficient that the weighted averaging be simply performed with respect to each of the first coefficients g of the FIR filter. Thus, the third coefficient γ can be derived by Equation (25) below.

$$\begin{matrix}[ Equation 25 ] & \\ \{ γ \} = \{ \frac{{\sum }_{i} {L}_{i} \times {\{ g \}}_{i}}{{\sum }_{i} {L}_{i}} \} & ( 25 )\end{matrix}$$

Next, the inverse system identification unit 311 performs the processing S44 for determining the second coefficient h configuring the IIR filter based on the third coefficient γ, and identifying the inverse system for the subject to control 2, the inverse system including the second coefficient h and the part (γ₁) of the third coefficient γ. Here, the same processing as the processing S2 in the first embodiment is performed while simply replacing the first coefficient g of the processing S2 with the third coefficient γ.

Next, the feed-forward compensation unit 312 performs the processing S43 for calculating and estimating the input value uₜ using the inverse system identified by the inverse system identification unit 311. The processing for calculating and estimating the input value uₜ is the same as the processing S3 of the first embodiment, and it is sufficient that the first coefficient g of the processing S3 simply be replaced with the third coefficient γ.

### Operational Effects

As described above, the compensator 3 according to the present embodiment performs the processing S31 for estimating the likelihood of each of the plurality of model candidates based on the measured output values y, and the estimated value “\hat{ }y” of the output, which is obtained from the first coefficient g and the measured input values u, the processing S42 for deriving the third coefficient γ, which is the weighted average of the first coefficients g of each of the model candidates, using the likelihood as the weighting factor, the processing S44 for determining the second coefficient h configuring the IIR filter based on the third coefficient γ, and identifying the inverse system for the subject to control 2, the inverse system including the second coefficient h and the part (γ₁) of the third coefficient γ, and the processing S43 for estimating the input value uₜ to be input to the subject to control 2 from the weighted sum of the time history of the target values r of the output.

In this way, since the compensator 3 expresses the subject to control 2 by the weighted average of the model candidates, accuracy of the model can be improved. As a result, the compensator 3 can estimate the input value uₜ, which can improve the control accuracy, and provide the input value uₜ for the subject to control 2. Further, by expressing the subject to control 2 by the weighted average of the model candidates, the compensator 3 can express changes of the subject to control 2 with a small number of the model candidates.

### Fifth Embodiment

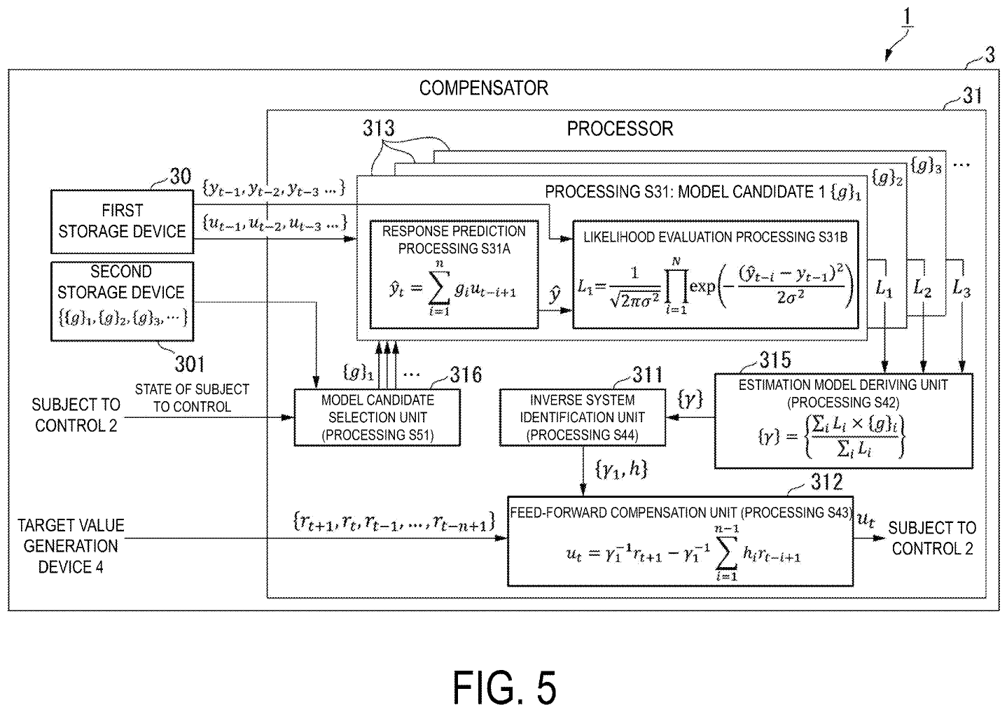

Next, the control system 1 according to a fifth embodiment of the present disclosure will be described with reference to FIG. 5.

The same components as those in the above-described embodiments will be denoted by the same reference signs, and a detailed description thereof will be omitted.

### Functional Configuration of Control System

FIG. 5 is a diagram illustrating a functional configuration of the control system according to the fifth embodiment of the present disclosure.

In the third and fourth embodiments described above, the compensator 3 estimates the likelihood for all of the plurality of models. However, if the calculation is performed for all of the model candidates, a disadvantage arises in terms of the calculation time.

Thus, the compensator 3 according to the present embodiment further performs, in a model candidate selection unit 316, processing S51 for selecting some of the models to be calculated, among the plurality of model candidates.

### Processing Flow of Compensator

Here, an aspect in which the function of the model candidate selection unit 316 is added to the compensator 3 according to the fourth embodiment will be described. Note that, in the other embodiments, the function of the model candidate selection unit 316 may be added to the compensator 3 according to the third embodiment.

The model candidate selection unit 316 acquires a state of the subject to control 2, and performs the processing S51 for selecting only the model candidates indicating that state. For example, when the subject to control 2 is a power generation plant, an electrical output (80%, for example) of the power generation plant is acquired as a state, and only the model candidates corresponding to the electrical output (the model candidates corresponding to an electrical output of 60% to 80%, for example) are selected from the plurality of model candidates. Further, when the subject to control 2 is a machine tool, the model candidate selection unit 316 may acquire the movement speed, direction, arrangement, and the like of the machine as a state of the subject to control 2.

Further, the likelihood estimation unit 313 estimates the likelihood of only the model candidates selected by the model candidate selection unit 316. Note that specific content of the processing for estimating the likelihood is the same as the processing S31 of the third and fourth embodiments described above.

### Operational Effects

As described above, the compensator 3 according to the present embodiment further performs the processing S51 for selecting, among the plurality of model candidates, the model candidates corresponding to the state of the subject to control. Further, in the processing S31 for estimating the likelihood, the compensator 3 estimates the likelihood of the selected model candidates.

In this way, the compensator 3 can reduce the number of model candidates for which the likelihood is estimated, and the computation load can thus be reduced.

### Sixth Embodiment

The first to fifth embodiments described above are applicable to systems for controlling various types of the subject to control 2. For example, as described in the present application example, the control system 1 according to each of the above-described embodiments may be used as a control system for a power generator. Note that, for ease of explanation, an example will be described in which the control system 1 according to the first embodiment is used as the control system for the power generator.

Demand for power constantly changes in accordance with circumstances of customers. Thus, in a power system, the power source, which is represented by the power generation plant, adjusts the power to be supplied in order to balance supply and demand. Specifically, in a thermal power plant provided with a gas turbine, a steam turbine, or the like, the rotational speed of the power generator driven by the gas turbine is maintained at a reference value corresponding to, for example, 60 Hz. For the power system, a change in demand is a disturbance, and when the demand exceeds supply, the frequency decreases, and conversely, when the demand is insufficient, the frequency increases. When the power system is in a settled state, the rotational speed of the power generator perfectly matches a value corresponding to the frequency. In a thermal power plant, the rotational speed of the power generator is thus maintained at the reference value. Specifically, when the rotational speed decreases, the output of the gas turbine is increased, and when the rotational speed increases, the gas turbine is operated while increasing or decreasing the fuel or the flow rate of steam so that the output of the gas turbine is reduced. However, after an increase in the output of the gas turbine, there is a delay before an actual increase in the power generating capacity, and thus, an error occurs in the rotational speed. The greater the disturbance, the more prominently the error appears. This delay is caused by two factors, namely, the inertia of the gas turbine and the power generator, and admittance (ease of flow of electricity) of the power generator and the power system. Of those, the value of the latter changes in accordance with the load of the power generator and the power system. When the change is large, a frequency fluctuation occurs in the power system, and power quality significantly deteriorates. Thus, the compensator 3 according to each of the above-described embodiments is used to perform control for reducing the frequency fluctuation.

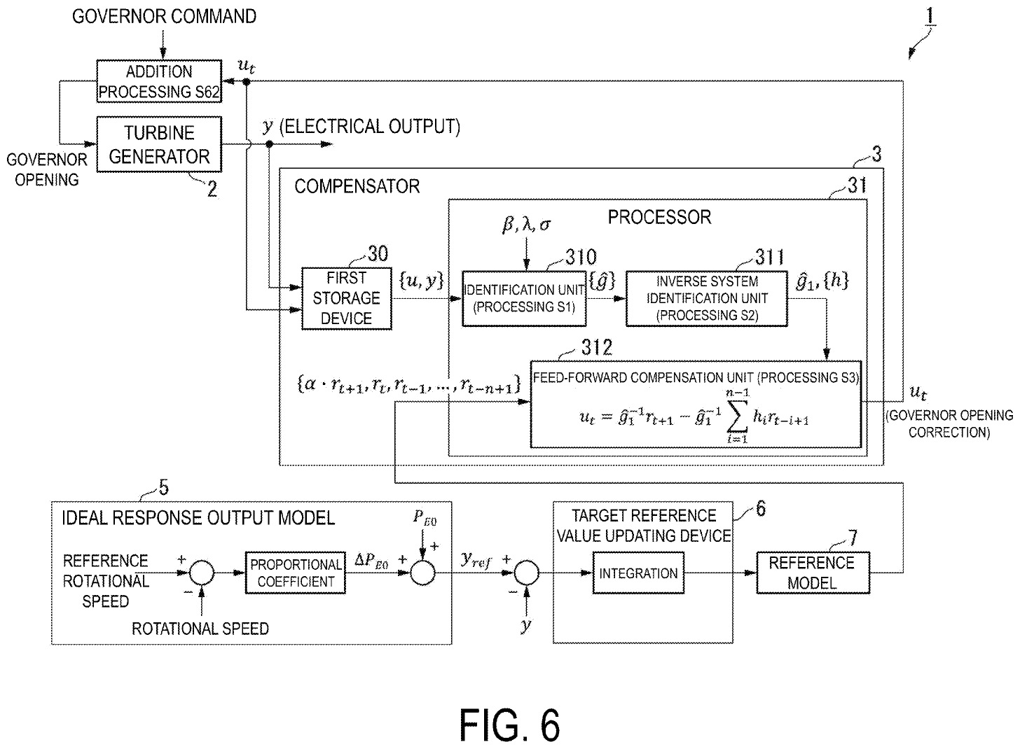

FIG. 6 is a diagram illustrating a functional configuration of the control system according to a sixth embodiment. FIG. 6 illustrates an example in which the control system according to at least one of the embodiments of the present disclosure is used as the control system for the power generator.

As illustrated in FIG. 6, in the present embodiment, the subject to control 2 is a turbine generator. Further, of the compensators 3 according to the present disclosure, the compensator 3 according to the first embodiment is used.

In each of the above-described embodiments, a target value r is a given value. However, the method in which the target value is a given value is not useful for suppressing the frequency fluctuation of the power system. This is because the value for the target value is predetermined, and the frequency fluctuation, which is constantly taking place, is not reflected in the value. The present embodiment is conceived to improve the above-described point, and configured to update the target value based on the constantly changing frequency and suppress the frequency fluctuation. Although the present embodiment is described using a power generator as the subject to control, the present disclosure can be generally applied to a subject to control that is influenced by disturbances or characteristics variation.

In the present embodiment, the output y is an electrical output of the turbine generator 2. The input u is a governor opening correction. The control system 1 according to the present embodiment is configured by adding an ideal response output model 5, a target reference value updating device 6, and a reference model 7 to the first embodiment. The ideal response output model 5 is a model that outputs a reference value of the output y of the subject to control 2. In the turbine generator 2, a reference output y_{ref} is a value obtained by adding a constant term P_{E0} to an electrical output adjustment amount ΔP_{E0}, which is determined by multiplying a rotational error of the turbine generator 2, that is, a difference between a rotational speed corresponding to the reference value of the frequency and an actual rotational speed, by a proportional coefficient.

In particular, the target reference value updating device 6 performs computation at a cycle at least twice as long as the computation cycle of the input u to update a target reference value r₀. For example, if the computation cycle is five times longer, the target reference value is updated at a cycle five times longer than the computation cycle of the input u, as in r₀ᵢ(i=1, 6, 11, . . . ). The most recently updated value is substituted for the values between the computation cycles of the target reference value r₀. For example, the value of r₀₁ is substituted for r₀₅, r₀₄, r₀₃, and r₀₂. The simplest operation for updating the target reference value r₀ is, for example, an integration operation. The most basic example is adding the difference between the reference output y_{ref} and the actual output y to the immediately preceding value of r₀. Furthermore, since the target reference value updating device 6 has a long computation cycle, a smoothing filter may be provided for removing a noise component included in the difference between the reference output y_{ref} and the actual output y. The smoothing filter performs calculation at the computation cycle of the input u.

The reference model 7 aligns the updating cycle of the control input u with the updating cycle of the target reference value r₀. As described above, since the target reference value r₀ is updated every five steps, for example, the target reference value r₀ changes in a stepwise manner. Thus, for example, a filter such as a primary delay filter is used as the reference model, and computation is performed for this filter at the updating cycle of the control input u, to update the target reference value r₀. For example, the target value r is generated that should be followed by the output y during the five steps. If the target reference value is updated every five steps as in r₀ᵢ (i=1, 6, 11, . . . ), the reference model inputs the time history of the target reference values r₀ in which the values are updated every five steps as in {r₀₁, r₀₁, r₀₁, r₀₁, r₀₁, r₀₆, r₀₆, r₀, r₀₆, r₀₆, r₀₁₁, r₀₁₁, r₀₁₁, r₀₁₁, r₀₁₁, . . . , updates the target value r for every step as in {r₁, r₂, r₃, r₄, r₅, r₆, r₇, r₈, r₉, r₁₀, r₁₁, r₁₂, r₁₃, r₁₄, r₁₅, . . . }, and uses the target value r as an input for the feed-forward compensation unit 312.

At addition processing S62, the control input u calculated by the compensator 3 is added to an existing governor command, and then used to control the turbine generator 2.

In this way, by applying the compensator 3 according to the first embodiment to the control system 1 of the turbine generator 2, the control accuracy is improved. Note that the same effects can be achieved by applying the compensator 3 according to each of the second to fifth embodiments to the control system 1 of the turbine generator 2. Furthermore, the present embodiment is not limited to the turbine generator. For example, the present embodiment can be applied to compensation performed when an aircraft or a ship deviates from a planned trajectory due to wind or tides, compensation performed when a steam temperature or a pressure of a boiler deviates from a set value, and the like.

### Seventh Embodiment

Further, the compensator 3 according to each of the above-described embodiments may be applied to a communication network or an equalizer, as will be described in the present embodiment. Here, for ease of explanation, an example will be described in which the control system 1 according to the first embodiment is used as an equalizer of a communication network.

When there is a delay or characteristics variation in a transmission path through which a signal is transmitted in a communication network or an electronic circuit, distortion may arise in the signal waveform, and an error may occur in data determination. In this case, an equalizer (or an equalizing circuit) is used to perform shaping (equalization) of the signal waveform in order to reduce the data determination error. However, since a different transmission path may be followed each time communication is performed, characteristics of a medium such as atmospheric air or an electric wire, which is the transmission path, change over time. In addition, the characteristics of the medium also change over time as a result of being affected by environmental temperature, performance deterioration, and the like. For this reason, the equalizer for the signal waveform is required to track the characteristics variation.

In known technology, the equalization of the signal waveform is performed by using an equalizer including a compensation filter and an adaptive filter. The compensation filter is configured as an infinite impulse response filter (IIR filter) that samples an impulse response waveform of the transmission path, which is a subject to be equalized. However, in the known technology, it is necessary to acquire the impulse response by imparting an impulse to the subject to be equalized in advance, and as a result, the compensation filter remains fixed while it is used in a shared manner. Thus, in the known technology, changes over time cannot be equalized, and thus, the adaptive filter is arranged on a downstream stage of the compensation filter to adjust the equalization characteristics. Even if the impulse response can be measured by imparting an impulse during the shared use, the IIR filter diverges due to the value of the coefficient. Thus, when the measured impulse response is directly used as the coefficient of the IIR filter, reliability may decrease.

Thus, in the present embodiment, an example will be described in which the compensator 3 is applied to the equalizing circuit, in place of the known compensation filter and adaptive filter.

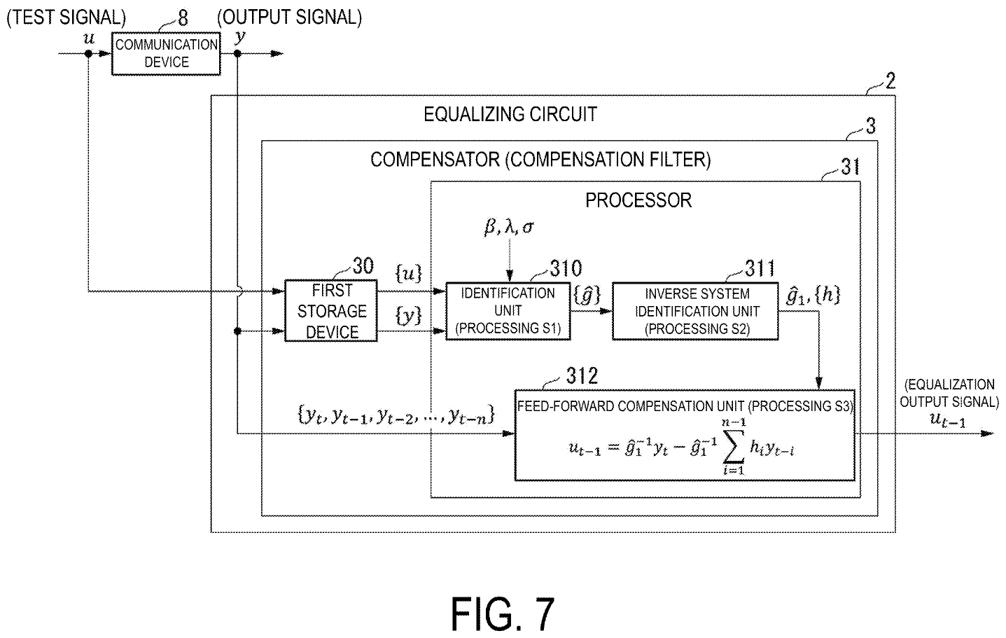

FIG. 7 is a diagram illustrating a functional configuration of the control system according to a seventh embodiment of the present disclosure.

For example, the compensator 3 according to the first embodiment is applied to an equalizing circuit 2 as a compensation filter. The identification unit 310 identifies an impulse response [\hat{ }g] of the subject to be equalized, from a test signal u, which is input to a communication device 8, and a response (an output signal of the communication device 8) y to the test signal u (the processing S1). Next, the inverse system identification unit 311 identifies the inverse system and an impulse response {h} thereof, based on the impulse response [\hat{ }g] (the processing S2). The feed-forward compensation unit 312 calculates and estimates an equalization output signal uₜ₋₁ based on the inverse system (the processing S3). An equalization output signal uₜ is a signal for which distortion by the transmission path has been compensated. As a result, the compensator 3 can improve the communication quality.

### Hardware Configuration

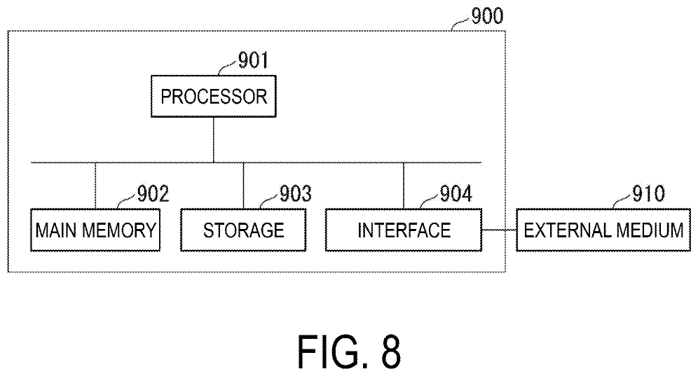

FIG. 8 is a diagram illustrating an example of a hardware configuration of the compensator 3 and the target value generation device 4 according to at least one of the embodiments of the present disclosure.

As illustrated in FIG. 8, a computer 900 includes a processor 901, a main memory 902, a storage 903, and an interface 904.

The above-described compensator 3 and target value generation device 4 are each installed in the computer 900. An operation of each of the above-described processing units is stored in the form of programs in the storage 903. The processor 901 reads a program from the storage 903 to deploy the program in the main memory 902, and performs the above-described processing in accordance with the program. Further, the processor 901 secures, in the main memory 902, a storage area corresponding to each of the storage units described above in accordance with the program.

The program may be a program for achieving some of the functions that the computer 900 is caused to perform. For example, the program may be a program that achieves a function in combination with another program already stored in the storage 903, or in combination with another program installed on another device. Note that, in other embodiments, the computer 900 may include a custom large scale integrated circuit (LSI) such as a programmable logic device (PLD), in addition to or in place of the configuration described above. Examples of the PLD include a programmable array logic (PAL), a generic array logic (GAL), a complex programmable logic device (CPLD), and a field programmable gate array (FPGA). In this case, some or all of the functions achieved by the processor 901 may be achieved by the integrated circuit.

Examples of the storage 903 include a magnetic disk, a magneto-optic disk, an optical disk, and a semiconductor memory. The storage 903 may be an internal medium directly connected to a bus of the computer 900, or may be an external medium 910 connected to the computer 900 via the interface 904 or a communication line. Further, when this program is distributed to the computer 900 through a communication line, the computer 900 that has received the distribution may deploy this program on the main memory 902 to perform the processing described above. In at least one of the embodiments, the storage 903 is a non-temporary tangible storage medium.

Further, the program may achieve some of the functions described above. Furthermore, the program may be a so-called differential file (a differential program) that achieves the functions described above in combination with another program already stored in the storage 903.

Although the embodiments of the present disclosure have been described above in detail, the present disclosure is not limited to those embodiments, and some design changes and the like may also be made to the present disclosure without departing from the technical concept of the present disclosure.

### Notes

The compensator, the control system, the compensation method, and the program described in the embodiments above are understood as follows, for example.

According to a first aspect of the present disclosure, a compensator (3) includes a processor (31), and a storage device (30) connected to the processor and configured to store a measured input value that is a measured value of an input to a subject to control (2) and a measured output value that is a measured value of an output from the subject to control. The processor performs processing for identifying, from the measured input value and the measured output value, a first coefficient configuring a finite impulse response filter (FIR filter), processing for determining, based on the first coefficient, a second coefficient configuring an autoregression filter (AF filter), and identifying an inverse system, including the second coefficient and a part of the first coefficient, for the subject to control, and processing for estimating an input value to be input to the subject to control from a weighted sum of the target value of the output set in accordance with a time, based on the inverse system. As a result, by identifying the first coefficient configuring the FIR filter, the compensator can update a model for the subject to control with a smaller number of data points than that of a known system. Further, in a known kernel-type system identification method, since an amount of calculation becomes enormous when all of the first coefficients of the FIR filters are used, it is difficult to calculate the inverse system including all of the first coefficients. However, the compensator according to the present embodiment can easily identify the inverse system by limiting the first coefficients to be used to only some of the first coefficients. Furthermore, in a known ARMA transfer function model, the numerical calculation may diverge depending on the value, as described above. However, since the compensator according to the present embodiment calculates the input value from the weighted sum of the time history of the target value, the divergence of the numerical calculation can be suppressed. Therefore, the compensator can accurately calculate the input value to be input to the subject to control from a small amount of data.

According to a second aspect of the present disclosure, a compensator (3) includes a processor (31) and a storage device (30) connected to the processor and configured to store an measured input value that is a measured value of the input to the subject to control (2) and a measured output value that is a measured value of the output from the subject to control. The processor performs processing for determining, from the measured input value and the measured output value, a first coefficient configuring an autoregression filter (AF filter) and a second coefficient, and identifying an inverse system, including the second coefficient and a part of the first coefficient, for the subject to control, and processing for calculating an input value to be input to the subject to control from a weighted sum of the target value of the output set in accordance with a time, based on the inverse system.

In this way, the compensator can directly derive a prediction model using the AR filter without performing processing for deriving the prediction model using the FIR filter. As a result, the compensator can use a simplified series of processes for determining the input value.

According to a third aspect of the present disclosure, a compensator (3) includes a processor (31), and a storage device (30) connected to the processor and configured to store, in advance, a measured input value that is a measured value of an input to a subject to control, a measured output value that is a measured value of an output from the subject to control, a plurality of first coefficients respectively configuring a plurality of model candidates for the subject to control, and an inverse system that corresponds to each of the plurality of model candidates. The processor performs processing for estimating a likelihood of each of the plurality of model candidates based on the measured output value and an estimated value of the output obtained from the plurality of first coefficients and the measured input value, processing for selecting the model candidate having the highest estimated likelihood, and processing for calculating an input value to be input to the subject to control from a weighted sum of the target value of the output set in accordance with a time, based on the inverse system corresponding to the selected model candidate.

In this way, the compensator does not perform real-time computation for the identification, and thus, computation load can be reduced. Further, since the compensator creates the inverse system in advance, it is possible to reduce the risk of not being able to calculate the inverse system due to the divergence of the numerical calculation.

According to a fourth aspect of the present disclosure, a compensator (3) includes a processor (31), and a storage device (30) connected to the processor and configured to store, in advance, a measured input value that is a measured value of an input to a subject to control, a measured output value that is a measured value of an output from the subject to control, and a plurality of first coefficients respectively configuring a plurality of model candidates for the subject to control. The processor performs processing for estimating a likelihood of each of the plurality of model candidates based on the measured output value and an estimated value of the output obtained from the plurality of first coefficients and the measured input value, processing for deriving a third coefficient that is a weighted average of the first coefficient of each of the model candidates, using the likelihood as a weighting factor, processing for determining, based on the third coefficient, a second coefficient configuring an autoregression filter, and identifying an inverse system, including the second coefficient and a part of the third coefficient, for the subject to control, and processing for estimating an input value to be input to the subject to control from a weighted sum of the target value of the output set in accordance with a time, based on the inverse system.

In this way, the compensator expresses the subject to control by the weighted average of the model candidates, and thus, accuracy of the model can be improved. As a result, the compensator can estimate the input value, which can improve the control accuracy, and provide the input value for the subject to control. Further, by expressing the subject to control by the weighted average of the model candidates, the compensator can express changes of the subject to control with a small number of the model candidates.

According to a fifth aspect of the present disclosure, the compensator according to the third or fourth aspect further performs processing for selecting, from the plurality of model candidates, the model candidate corresponding to a state of the subject to control, and in the processing for estimating the likelihood, the compensator estimates the likelihood of the selected model candidate.

In this way, the compensator can reduce the number of model candidates for which the likelihood is estimated, and thus, the computation load can be reduced.

According to a sixth aspect of the present disclosure, a control system (1) includes a compensator (3) according to any one of the first to fifth aspects, and a target value generation device (4) configured to generate a target value used for controlling the subject to control (2) based on an input value estimated by the compensator.

According to a seventh aspect of the present disclosure, a compensation method includes identifying a first coefficient configuring a finite impulse response filter from a measured input value that is a measured value of an input to a subject to control and a measured output value that is a measured value of an output from the subject to control, determining, based on the first coefficient, a second coefficient configuring an autoregression filter, and identifying an inverse system, including the second coefficient and a part of the first coefficient, for the subject to control, and estimating an input value to be input to the subject to control from a weighted sum of the target value of the output set in accordance with a time, based on the inverse system.

According to an eighth aspect of the present disclosure, a program causes a computer of a compensator to perform processing for identifying a first coefficient configuring a finite impulse response filter from a measured input value that is a measured value of an input to a subject to control and a measured output value that is a measured value of an output from the subject to control, processing for determining, based on the first coefficient, a second coefficient configuring an autoregression filter, and identifying an inverse system, including the second coefficient and a part of the first coefficient, for the subject to control, and processing for estimating an input value to be input to the subject to control from a weighted sum of the target value of the output set in accordance with a time, based on the inverse system.

While preferred embodiments of the invention have been described as above, it is to be understood that variations and modifications will be apparent to those skilled in the art without departing from the scope and spirits of the invention. The scope of the invention, therefore, is to be determined solely by the following claims.

1. A compensator comprising:
a processor; and
a storage device connected to the processor and configured to store a measured input value that is a measured value of an input to a subject to control and a measured output value that is a measured value of an output from the subject to control;
the processor performing
processing for identifying, from the measured input value and the measured output value, a first coefficient configuring a finite impulse response filter,
processing for determining, based on the first coefficient, a second coefficient configuring an infinite impulse response filter, and identifying an inverse system that is a system including the second coefficient and a part of the first coefficient and configured to identify a target value of the input from a target value of the output of the subject to control, and
processing for compensating for an input value to be input to the subject to control from a weighted sum of the target value of the output set in accordance with a time, based on the inverse system.

2. A compensator comprising:
a processor; and
a storage device connected to the processor and configured to store a measured input value that is a measured value of an input to a subject to control and a measured output value that is a measured value of an output from the subject to control;
the processor performing
processing for determining, from the measured input value and the measured output value, a second coefficient configuring an infinite impulse response filter, and identifying an inverse system that is a system including the second coefficient and configured to identify a target value of the input from a target value of the output from the subject to control, and
processing for calculating an input value to be input to the subject to control from a weighted sum of the target value of the output set in accordance with a time, based on the inverse system.

3. A compensator comprising:
a processor; and
a storage device connected to the processor and configured to store, in advance, a measured input value that is a measured value of an input to a subject to control, a measured output value that is a measured value of an output from the subject to control, a plurality of first coefficients respectively configuring a plurality of model candidates for the subject to control, and an inverse system that corresponds to each of the plurality of model candidates, the inverse system being configured to identify a target value of the input from a target value of the output from the subject to control;
the processor performing
processing for estimating a likelihood of each of the plurality of model candidates based on the measured output value, and an estimated value of the output obtained from the plurality of first coefficients and the measured input value,
processing for selecting the model candidate having the highest estimated likelihood, and
processing for calculating an input value to be input to the subject to control from a weighted sum of the target value of the output set in accordance with a time, based on the inverse system corresponding to the selected model candidate.

4. A compensator comprising:
a processor; and
a storage device connected to the processor and configured to store, in advance, a measured input value that is a measured value of an input to a subject to control, a measured output value that is a measured value of an output from the subject to control, and a plurality of first coefficients respectively configuring a plurality of model candidates for the subject to control;
the processor performing
processing for estimating a likelihood of each of the plurality of model candidates based on the measured output value, and an estimated value of the output obtained from the plurality of first coefficients and the measured input value,
processing for deriving a third coefficient that is a weighted average of the first coefficient of each of the model candidates, using the likelihood as a weighting factor,
processing for determining, based on the third coefficient, a second coefficient configuring an infinite impulse response filter, and identifying an inverse system that is a system including the second coefficient and a part of the third coefficient and configured to identify a target value of the input from a target value of the output from the subject to control, and
processing for estimating an input value to be input to the subject to control from a weighted sum of the target value of the output set in accordance with a time, based on the inverse system.

5. The compensator according to claim 3, wherein
the compensator further performs processing for selecting, from the plurality of model candidates, the model candidate corresponding to a state of the subject to control, and
in the processing for estimating the likelihood, the compensator estimates the likelihood of the selected model candidate.

6. The compensator according to claim 4, wherein
the compensator further performs processing for selecting, from the plurality of model candidates, the model candidate corresponding to a state of the subject to control, and
in the processing for estimating the likelihood, the compensator estimates the likelihood of the selected model candidate.

7. A control system comprising:
the compensator according to claim 1; and
a target value generation device configured to generate a target value used for controlling the subject to control based on an input value estimated by the compensator.

8. A compensation method comprising:
identifying a first coefficient configuring a finite impulse response filter from a measured input value that is a measured value of an input to a subject to control and a measured output value that is a measured value of an output from the subject to control;
determining, based on the first coefficient, a second coefficient configuring an infinite impulse response filter, and identifying an inverse system that is a system including the second coefficient and a part of the first coefficient and configured to identify a target value of the input from a target value of the output from the subject to control; and
estimating an input value to be input to the subject to control from a weighted sum of the target value of the output set in accordance with a time, based on the inverse system.

9. A non-transitory computer readable medium storing a program causing a computer of a compensator to perform:
processing for identifying a first coefficient configuring a finite impulse response filter from a measured input value that is a measured value of an input to a subject to control and a measured output value that is a measured value of an output from the subject to control;
processing for determining, based on the first coefficient, a second coefficient configuring an infinite impulse response filter, and identifying an inverse system that is a system including the second coefficient and a part of the first coefficient and configured to identify a target value of the input from a target value of the output from the subject to control; and
processing for estimating an input value to be input to the subject to control from a weighted sum of the target value of the output set in accordance with a time, based on the inverse system.
